(19) United States
(12) Patent Application Publication
(10) Pub. No.: US 2008/0164602 A1
(43) Pub. Date: Jul. 10, 2008

(54) CAP PACKAGE FOR MICRO ELECTRO-MECHANICAL SYSTEM CAPABLE OF MINIMIZING ELECTRO-MAGNETIC INTERFERENCE

(75) Inventors: Jiung-Yue TIEN, Taichung County (TW); Ming-Te Tu, Taichung County (TW); Chin-Ching Huang, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/766,391

(22) Filed: Jun. 21, 2007

(30) Foreign Application Priority Data
Jan. 4, 2007 (TW) 96200166

(51) Int. Cl. H01L 23/12

(52) U.S. Cl. 257/704; 257/E23.181

(57) ABSTRACT

A cap package for MEMS includes a substrate, a cap made of a carbon added plastic material and capped on the substrate to define with the substrate an accommodation chamber, and a chip mounted on the substrate and located inside the accommodation chamber. The substrate has a conducting portion electrically connected with the cap and grounded.

### BACKGROUND OF THE INVENTION

1. Field of the Invention

The present invention relates generally to cap package for micro electromechanical system (hereinafter referred to as “MEMS”) and more particularly, to a cap package for MEMS, which can minimize the electromagnetic interference (hereinafter referred to as “EMI”).

2. Description of the Related Art

Cap package is intensively used in the fabrication of an electronic product to protect electronic components. In a conventional cap package manufacturing process, a metal cap is used for cap package. However, shape forming from a single metal plate to a desired profile of metal cap is relatively difficult in manufacturing. Normally, a metal cap in a cap package is made by joining multiple metal elements together. This manufacturing procedure is time-consuming. Further, the conventional cap package can hardly isolate electro-magnetic interference (EMI). The electronic component encapsulated in the cap package may be interfered with electromagnetic noises easily, thereby lowering the working efficiency. That is, the shielding effectiveness of the conventional cap package is not good.

Therefore, it is desirable to provide a cap package for MEMS, which can eliminate the aforesaid drawbacks.

### SUMMARY OF THE INVENTION

The present invention has been accomplished under the circumstances in view. It is therefore one objective of the present invention to provide a cap package, which can minimize electro-magnetic interference.

To achieve this objective of the present invention, the invention provides a cap package for MEMS, which comprises a substrate, a cap and a chip. The cap is injection-molded from a carbon added plastic material and capped on the substrate, thereby defining with the substrate an accommodation chamber. The chip is mounted on the substrate and located inside the accommodation chamber.

In an embodiment of the present invention, the substrate has a conducting portion electrically connected with the cap and grounded. The present invention uses carbon to make a non-metal cap electrically conductive, thereby effectively minimizing the EMI. In other word, the cap package provided by the present invention can eliminate the drawbacks of the conventional cap package.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing a cap package for MEMS in accordance with a first preferred embodiment of the present invention, and

FIG. 2 a schematic drawing showing a cap package for MEMS in accordance with a second preferred embodiment of the present invention.

### DETAILED DESCRIPTION OF THE INVENTION

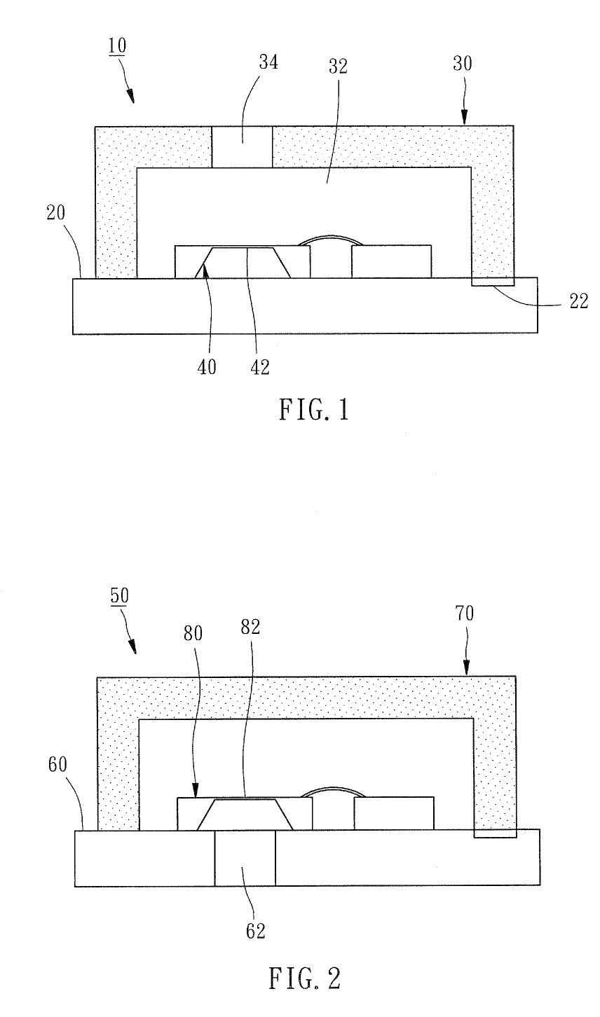

As shown in FIG. 1, a cap package 10 for MEMS in accordance with a first preferred embodiment of the present invention comprises a substrate 20, a cap 30 and a chip 40.

The substrate 20 has a conducting portion 22 electrically connected to the cap 30 and grounded.

The cap 30 is molded from a carbon added plastic material by injection molding technology, having a resistivity smaller than 10² Ωm (ohm-meter). The cap 30 is capped on the substrate 20, defining an accommodation chamber 32. The cap 30 has an opening 34.

The chip 40 is installed on the substrate 20 inside the accommodation chamber 32. The chip 40 has an action zone 42 facing the opening 34. The action zone 42 is a thin film at the center of the chip 40.

The cap 30 of the cap package 10 is grounded to isolate external EMI, prohibiting external electromagnetic noises from entering the accommodation chamber 32 to interfere with the chip 40. Therefore, the cap package 10 of the present invention effectively isolates electromagnetic interference, i.e., the invention eliminates the drawbacks of the conventional cap package. Further, because the cap is made by injection molding technology, the fabrication of the cap is easy.

FIG. 2 illustrates a cap package 50 for MEMS in accordance with a second preferred embodiment of the present invention. Similar to the aforesaid first embodiment, the cap package 50 comprises a substrate 60, a cap 70 and a chip 80. According to this embodiment, the substrate 60 has an opening 62 facing the action zone 82 of the chip 80, and the cap 70 fully shields the chip 80.

Except the opening 62 at the substrate 60 to substitute for the opening 34 at the cap 30 in the aforesaid first embodiment, the cap package 50 of the second preferred embodiment of the present invention has the same features of the aforesaid first preferred embodiment. Therefore, this second embodiment achieves the same effect as the aforesaid first preferred embodiment.

As indicated above, the cap package for MEMS of the present invention uses carbon to make a non-metal cap electrically conductive, so that the cap package can effectively minimize the electromagnetic interference. Further, the cap is made by injection molding technology, and therefore the cap of the cap package of the present invention is easy to make.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A cap package for micro electro-mechanical system, comprising:
a substrate;
a cap made of a carbon added plastic material and capped on the substrate to define with the substrate an accommodation chamber; and
a chip mounted on the substrate and located inside the accommodation chamber.

2. The cap package as claimed in claim 1, wherein the cap has a resistivity smaller than 10² Ωm (ohm-meter).

3. The cap package as claimed in claim 1, wherein the substrate has a conducting portion electrically connected with the cap.

4. The cap package as claimed in claim 3, wherein the conducting portion of the substrate is grounded.

5. The cap package as claimed in claim 1, wherein the cap is made by injection molding.

6. The cap package as claimed in claim 1, wherein the cap has an opening and the chip has an action zone facing the opening.

7. The cap package as claimed in claim 1, wherein the substrate has an opening and the chip has an action zone facing the opening.
